(19) United States
(12) Patent Application Publication
(10) Pub. No.: US 2015/0295094 A1
(43) Pub. Date: Oct. 15, 2015

(54) THIN FILM TRANSISTOR, MANUFACTURING METHOD THEREOF, ARRAY SUBSTRATE AND DISPLAY DEVICE

(71) Applicant: BOE TECHNOLOGY GROUP CO., LTD., Chaoyang District, Beijing (CN)

(72) Inventors: Qingrong Ren, Beijing (CN); Wei Guo, Beijing (CN); Qianqian Bu, Beijing (CN); Lei Zhao, Beijing (CN); Lu Wang, Beijing (CN); Zhiqiang Jiang, Beijing (CN)

(21) Appl. No.: 14/342,234

(22) PCT Filed: Jul. 29, 2013
(86) PCT No.: PCT/CN2013/080280

§ 371 Date: Feb. 28, 2014

(30) Foreign Application Priority Data
Apr. 17, 2013 (CN) 201310133306.X

(51) Int. Cl. H01L 29/786; H01L 21/306; H01L 29/45; H01L 21/285; H01L 29/66; H01L 21/02

(52) U.S. Cl. CPC H01L 29/78675; H01L 29/66757; H01L 21/02532; H01L 21/02592; H01L 21/02667; H01L 29/456; H01L 21/28568; H01L 21/30604

(57) ABSTRACT

A thin film transistor, a manufacturing method thereof, an array substrate and a display device are provided. The method for manufacturing the thin film transistor including: forming an active layer; forming an etch barrier layer on the active layer at a position for forming interlayer via holes subsequently; forming an insulating layer on the active layer and the etch barrier layer, and forming the interlayer via holes in the insulating layer to expose the etch barrier layer.

### FIELD OF THE INVENTION

Embodiments of the present invention relate to a thin film transistor, a manufacturing method thereof, an array substrate, and a display device.

### BACKGROUND

Most of the current displays are based on amorphous (a-Si), i.e., a thin film transistor (TFT) of the display panels adopts an amorphous silicon material. It is considered that polysilicon (Poly-Si) with high electron mobility is a better material for manufacturing TFT comparing with amorphous silicon.

As illustrated in FIG. 1, a conventional polysilicon array substrate comprises from bottom to top: a substrate 10, a buffer layer 11 (a laminated structure of SiOₓ/SiNₓ) disposed on the substrate 10, a polysilicon active layer 12, a gate insulating layer 13, a gate electrode 14 and an interlayer insulating layer (ILD) 15, and further comprises a source/drain metal layer (source/drain electrodes) disposed on the interlayer insulating layer 15 (not illustrated), the source/drain electrodes being contacted with and communicated with the polysilicon active layer 12 through interlayer via holes 100. The interlayer insulating layer 15 not only requires good coverage performance and insulating effect, but also requires high light transmittance. In order to achieve the above objects and to resist moisture and external mechanical scratching, materials such as SiOₓ, SiNₓ or a stacked structure of SiOₓ/SiNₓ are usually used as the interlayer insulating layer 15. Specific embodiments mostly adopt the laminated structure of SiOₓ/SiNₓ which has very good electrical properties. In addition, the gas for preparation of SiNₓ layer contains hydrogen, and a hydrogenation treatment can be performed on the existing films while forming the SiNₓ layer.

The inventors have found the following problems in prior art while forming the interlayer via holes 100.

The interlayer insulating layer 15 is generally thicker, and is a laminated structure. Further, the gate insulating layer 13 also needs to be etched while etching the interlayer insulating layer 15 for forming the interlayer via holes 100, and the films to be etched are too thick. In addition, compared with the polysilicon, etching of SiOₓ is of much difficulty. It is difficult to adjust a process with an excellent etch selectivity ratio, and the polysilicon active layer is relatively thin, so that it tends to appear that some region is not etched through and some region is over etched to lead to damage on the active layer, which seriously affects the product yield and the application of low-temperature polysilicon technology on a large-size display.

### SUMMARY

An embodiment of the present invention provides a method for manufacturing a thin film transistor (TFT), comprising:

forming an active layer;

forming an etch barrier layer on the active layer at a position for forming interlayer via holes subsequently;

forming an insulating layer on the active layer and the etch barrier layer, and forming the interlayer via holes in the insulating layer to expose the etch barrier layer.

In one example, forming the insulating layer comprises:

forming a gate insulating layer on the active layer provided with the etch barrier layer;

forming an interlayer insulating layer above the gate insulating layer.

In one example, the method further comprises:

after forming the gate insulating layer and before forming the interlayer insulating layer, forming a gate electrode on the gate insulating layer between two adjacent interlayer via holes; and

after forming the interlayer insulating layer, forming source/drain electrodes on the interlayer insulating layer, the source/drain electrodes being connected with the active layer through the interlayer via holes.

In one example, the etch barrier layer is a metal layer or a doped semiconductor layer.

In one example, the etching barrier layer is made of a material the same as that of the source/drain electrodes.

In one example, the etch barrier layer is one of a molybdenum metal film, an aluminum metal film, and a copper film, or one of a laminated structure of titanium/aluminum/titanium and a laminated structure of molybdenum/aluminum neodymium/molybdenum.

In one example, the active layer is a polysilicon active layer.

In one example, forming the active layer comprises:

forming a buffer layer on a substrate;

forming an amorphous silicon layer on the buffer layer;

converting the amorphous silicon layer into a polysilicon layer;

etching the polysilicon layer to form the active layer of the TFT;

doping partial regions of the active layer to form doped semiconductor regions;

alternatively, forming the active layer comprises:

forming a buffer layer on a substrate;

forming an amorphous silicon layer on the buffer layer;

converting the amorphous silicon layer into a polysilicon layer;

doping partial regions of the polysilicon layer to form doped semiconductor regions;

etching the doped polysilicon layer to form a polysilicon active layer of the TFT.

In one example, the etch barrier layer has a thickness of 500 Å˜3000 Å.

Another embodiment of the invention provides a thin film transistor (TFT), comprising:

an active layer;

an etch barrier layer used to protect the active layer upon etching interlayer via holes and disposed on the active layer at a position for forming the interlayer via holes; and

source/drain electrodes, electrically connected with the active layer through the interlayer via holes.

In one example, the thin film transistor further comprises:

a gate insulating layer disposed on the active layer and the etch barrier layer;

a gate electrode disposed on the gate insulating layer;

an interlayer insulating layer disposed above the gate electrode;

wherein the interlayer via holes penetrate through the interlayer insulating layer and the gate insulating layer thereunder.

In one example, the etch barrier layer is a metal layer or a doped semiconductor layer.

In one example, the etching barrier layer is made of a material the same as that of the source/drain electrodes.

In one example, the etch barrier layer is one of a molybdenum metal film, an aluminum metal film, and a copper film, or one of a laminated structure of titanium/aluminum/titanium and a laminated structure of molybdenum/aluminum neodymium/molybdenum.

In one example, the active layer is a polysilicon active layer.

In one example, the etch barrier layer has a thickness of 500 Å˜3000 Å.

Still another embodiment of the invention provides an array substrate, comprising the thin film transistor according to any embodiment of the invention.

Still another embodiment of the invention provides a display device, comprising the thin film transistor according to any embodiment of the invention.

Embodiments of the invention provide a thin film transistor and manufacturing method thereof, an array substrate, and a display device, the etch barrier layer is formed on the active layer at the position for forming the interlayer via holes subsequently, and the active layer 120 can be protected from being etched during forming the interlayer via holes using etching method. The problems such as uneven etching, insufficient etching or over etching of the interlayer insulating layer and etc. are solved and the product yield is improved.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a schematic sectional view of an array substrate;

FIG. 2 is a schematic view of an etch barrier layer on a thin film transistor according to a first embodiment of the invention;

FIG. 3 is a schematic view illustrating a flow process for forming a polysilicon active layer according to a second embodiment of the invention;

FIG. 4 is a schematic view illustrating a flow process for forming an etch barrier layer according to the second embodiment of the invention;

FIG. 5 is a schematic view of a gate insulating layer, a gate electrode, and an interlayer insulating layer according to the second embodiment of the invention;

FIG. 6 is a schematic view of forming interlayer via holes according to the second embodiment of the present invention;

FIG. 7 is a schematic view of a thin film transistor formed in the second embodiment of the present invention.

### DETAILED DESCRIPTION

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

Embodiments of the present invention provide an array substrate, a manufacturing method thereof, and a display device, which can solve the problem of uneven etching, insufficient etching, and over-etching of the interlayer insulating layer and etc, and improve the product yield.

### First Embodiment

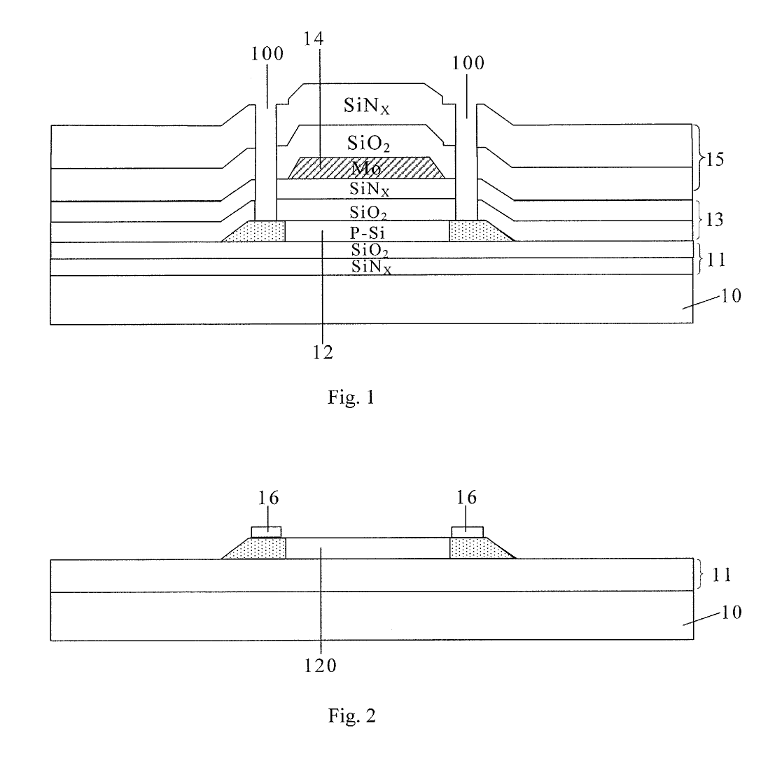

The embodiment provides a manufacturing method of a thin film transistor. As illustrated in FIG. 2, the method includes the following steps:

101, foaming an active layer 120; and after forming the active layer 120,

102, forming a etch barrier layer 16 on the active layer 120 at a position for forming interlayer via holes, so as to protect the active layer 120 upon the formation of the interlayer via holes, and the interlayer via holes (not illustrated in the figure) being used to connect the active layer 120 with source/drain electrodes (not illustrated in the figure).

After forming the etch barrier layer, an insulating layer may be formed on the active layer 120 and the etch barrier layer 16. The interlayer via holes are formed in the insulating layer to expose the etch barrier layer. After the source/drain electrodes are formed on the insulating layer, the source/drain electrodes are electrically connected with the active layer through the interlayer via holes, respectively. For example, the source/drain electrodes can be electrically connected with the active layer 120 through the etch barrier layer exposed through the via holes.

Herein, the insulating layer may include a gate insulating layer and an interlayer insulating layer which are sequentially stacked. A gate electrode is formed on the gate insulating layer at the position between two adjacent interlayer via holes. The source electrode and the drain electrode are electrically connected with the active layer through the two adjacent via holes.

The etch barrier layer may be formed at both end portions of the active layer, the two end portions may be doped regions to form a source region and a drain region of the TFT.

The via holes according to the present embodiment are via holes penetrating through all the layers between the active layer 120 and the source/drain electrodes, and the source electrode and the drain electrode are, respectively, electrically connected with the doped regions of the active layer 120.

For example, the material of the etch barrier layer 16 can be conductive metal or doped semiconductor, so as that the performance is achieved even some residual of the etch barrier layer is retained during etching, which will ensure that the active layer 120 is protected from being damaged during etching the interlayer via holes. Specifically, in the step, a metal film (or doped semiconductor layer) is deposited on the active layer 120, and the etch barrier layer 16 is formed by a photolithography process at the position for forming the interlayer via holes subsequently, and the etch barrier layer 16 is used to protect the active layer 120 during forming the interlayer via holes using an etching method, therefore, the etch barrier layer 16 should have a sectional area larger than that of the interlayer via holes.

The etch barrier layer 16 should have a sufficient thickness to ensure that the active layer 120 thereunder cannot be damaged in the case the insulating layer over the active layer 120 (for a TFT of top gate structure, it includes a gate insulating layer and an interlayer insulating layer) is completely etched. However, the etch barrier layer 16 cannot be too thick, so as to avoid high steps which may influence the deposition of layer deposited thereon. In some specific embodiments, the etch barrier layer 16 may generally have a thickness of 500 Å˜3000 Å.

The embodiment of the invention provides a method for manufacturing a thin film transistor, the etch barrier layer is formed on the active layer at the position for forming the interlayer via holes subsequently, and the active layer 120 can be protected from being etched during forming the interlayer via holes using etching method. The problems such as uneven etching, insufficient etching or over etching of the interlayer insulating layer and etc. are solved and the product yield is improved.

### Second Embodiment

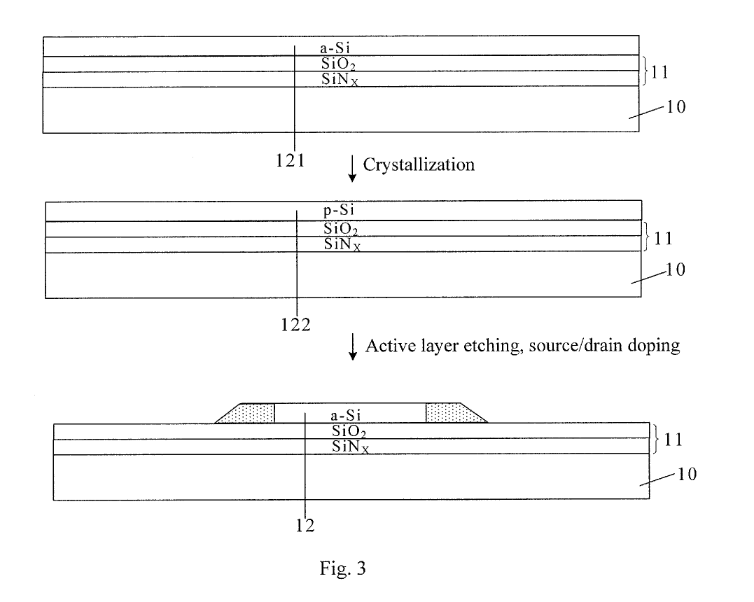

Further, an embodiment of the present invention provides a method for manufacturing a thin film transistor (TFT), as illustrated in FIGS. 3 to 5, the method includes:

201, forming a buffer layer 11 on a substrate 10;

202, forming an amorphous silicon layer 121 on the buffer layer 11;

203, converting the amorphous silicon layer 121 into a polysilicon layer 122;

204, etching the polysilicon layer to form an active layer 12 of the TFT;

205, doping partial regions of the active layer 12 to form doped semiconductor regions;

As illustrated in FIG. 3, optionally, in the steps 201 to 204, the buffer layer 11 and the amorphous silicon layer 121 are firstly deposited by chemical vapor deposition (PECVD), and then are subjected to dehydrogenation, and then the amorphous silicon layer 121 is converted into the polysilicon layer (P-Si) 122 by using an excimer laser crystallization method (ELA), and finally an active layer etching is performed on the polysilicon layer 122 by a photolithography process, and the source/drain doping is performed by using photoresist as a mask, so as to form the active layer 12 of the TFT. Of course, the source/drain doping can be firstly doped followed by the active layer etching (the order of these two steps may be reversed) and then activation by annealing is performed to activate the dopant ions.

For example, the buffer layer 11 may be a laminated structure of SiNₓ/SiO₂.

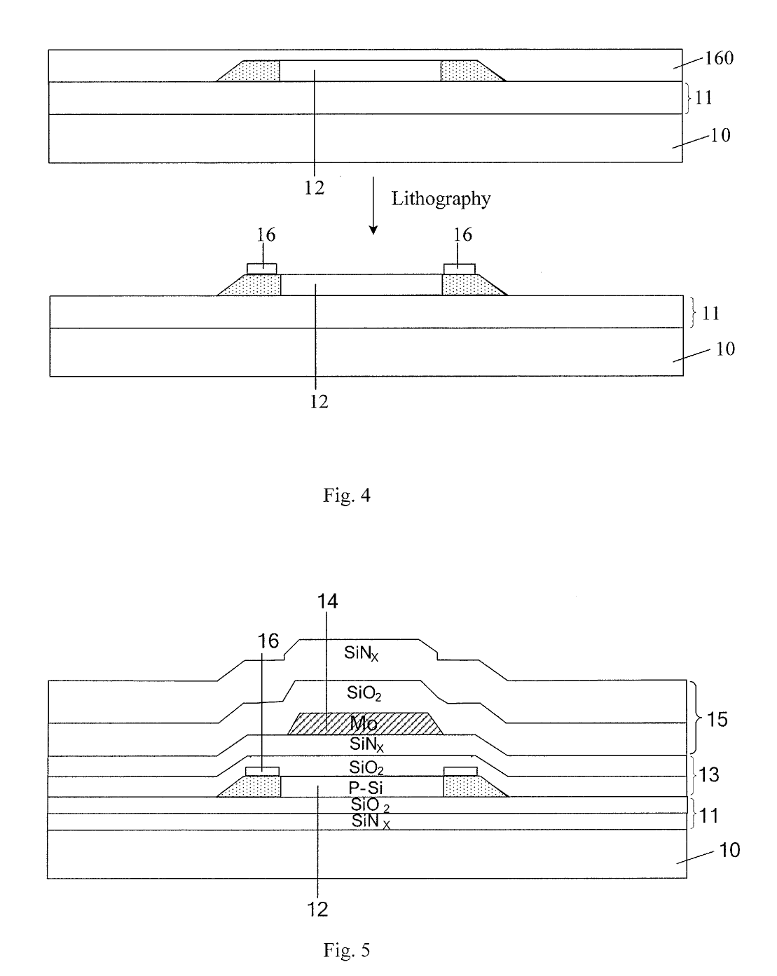

206, as illustrated in FIG. 4, depositing a metal layer 160, and forming an etch barrier layer 16 at a position for forming interlayer via holes subsequently through a patterning process;

In the present embodiment, the interlayer via holes are via holes penetrating through a gate insulating layer and an interlayer insulating layer, and the source and drain electrodes are electrically connected with the doped regions of the active layer 120 through the interlayer via holes, respectively.

In the step, the etch barrier layer 16 is formed on the doped polysilicon layer (active layer 12) for protecting the active layer via holes during etching the interlayer via holes. For example, the etch barrier layer 16 generally adopts materials the same as that of the source/drain electrodes, such as molybdenum (Mo), aluminum (Al), copper (Cu), etc., or a laminated structure of titanium/aluminum/titanium (Ti/Al/Ti), a laminated structure of molybdenum/aluminum neodymium/molybdenum (Mo/AlNd/Mo) or the like. When etching the interlayer via holes, the ohmic contact between the source/drain electrodes and the active layer cannot be affected even if some residual etch barrier layer 16 is retained during etching the interlayer via holes.

The etch barrier layer 16 adopts metals such as molybdenum (Mo), aluminum (Al), copper (Cu), or laminated structures of metals, and possesses a lower etching rate. In addition, such an etch barrier layer 16 can be slightly over etched or have some residual, which avoids bad process due to poor uniformity of etching and bad etch selectivity ratio.

207, forming a gate insulating layer 13 on the active layer 12 formed with the etch barrier layer 16;

208, forming a gate electrode 14 on the gate insulating layer 13;

209, forming an interlayer insulating layer 15 above the gate electrode 14;

As illustrated in FIG. 5, in steps 207 to 209, the gate insulating layer 12 and the gate metal layer are deposited on the active layer disposed with the etch barrier layer 16, the gate electrode 14 is formed by a photolithography process, and then the interlayer insulating layer 15 is deposited. The gate insulating layer 13 and the interlayer insulating layer 15 are laminated structure of SiOₓ/SiNₓ, and the gate electrode 14 is formed by etching the Mo metal film.

210, etching the interlayer insulating layer 15 and the gate insulating layer 13 thereunder to form interlayer via holes.

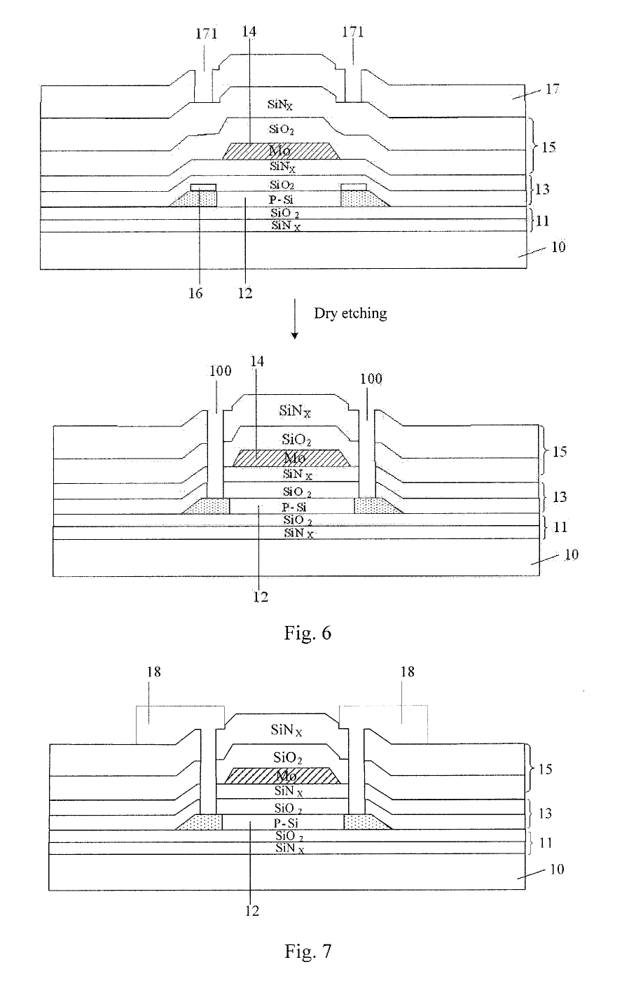

As illustrated in FIG. 6, in the step, the interlayer insulating layer 15 is coated with photoresist 17, and an etching window with the photoresist completely removed at the predetermined position for forming the interlayer via holes is formed after exposure and development, and then the interlayer insulating layer exposed in the etching window 171 is dry etched to remove the interlayer insulating layer 15 and the underlying gate insulating layer 13 at the etching window 171 and form interlayer via holes 100. Finally, the subsequent processes are performed to from a source electrode, a drain electrode, a pixel electrode (or a pixel electrode and a common electrode) and a passivation layer, so as to complete the thin film transistor. For example, as illustrated in FIG. 7, the source/drain electrodes 18 can be formed above the interlayer insulating layer. The source/drain electrodes 18 are electrically connected with the active layer through the interlayer via holes 100.

The embodiment of the present invention provides a method for manufacturing a thin film transistor, the etch barrier layer is formed on the polysilicon active layer at the position for forming the interlayer via holes subsequently, and the active layer 120 can be protected from being etched during forming the interlayer via holes using etching method. The problems such as uneven etching, insufficient etching or over etching of the interlayer insulating layer and etc. are solved and the product yield is improved.

### Third Embodiment

Correspondingly, other embodiments of the present invention further provide a thin film transistor comprising: an active layer; an etch barrier layer used to protect the active layer upon formation of interlayer via holes and disposed on the active layer at a position for forming the interlayer via holes; the interlayer via holes are used to connect the active layer with source/drain electrodes.

The thin film transistor further comprises:

A gate insulating layer disposed on the active layer and the etch barrier layer;

A gate electrode disposed on the gate insulating layer;

An interlayer insulating layer disposed above the gate electrode.

The interlayer via holes penetrate through the interlayer insulating layer and the underlying gate insulating layer.

Here, the interlayer via holes penetrate through the insulating layer above the active layer and the etch barrier layer (e.g., including the interlayer insulating layer and the gate insulating layer), so that the source/drain electrodes can be electrically connected to the active layer through the interlayer via holes.

The embodiment of the present invention provides a thin film transistor, the etch barrier layer is formed on the active layer at the position for forming the interlayer via holes subsequently, and the active layer 120 can be protected from being etched during forming the interlayer via holes using etching method. The problems such as uneven etching, insufficient etching or over etching of the interlayer insulating layer and etc. are solved and the product yield is improved.

Alternatively, the etch barrier layer is a metal layer or a doped semiconductor layer.

Alternatively, the etch barrier layer is made of materials the same as that of the source and drain electrodes.

Alternatively, the etch barrier layer is made of one of a molybdenum metal film, an aluminum metal film, and a copper film, or one of a laminated structure of titanium/aluminum/titanium and a laminated structure of molybdenum/aluminum neodymium/molybdenum.

Alternatively, the active layer is a polysilicon active layer.

Alternatively, the etch barrier layer has a thickness of 500 Å˜3000 Å.

Further, the present invention provides an array substrate including any one of the above mentioned thin film transistors.

The present invention further provides a display device including any one of the above mentioned thin film transistors.

As for the array substrate and the display device according to the invention, the etch barrier layer is formed on the active layer at the position for forming the interlayer via holes subsequently, and the active layer 120 can be protected from being etched during forming the interlayer via holes using etching method. The problems such as uneven etching, insufficient etching or over etching of the interlayer insulating layer and etc. are solved and the product yield is improved.

The foregoing is merely exemplary embodiments of the invention, but is not used to limit the protection scope of the invention. The protection scope of the invention shall be defined by the attached claims.

1. A method for manufacturing a thin film transistor, comprising:
forming an active layer;
forming an etch barrier layer on the active layer at a position for forming interlayer via holes subsequently;
forming an insulating layer on the active layer and the etch barrier layer, and forming the interlayer via holes in the insulating layer to expose the etch barrier layer.

2. The method according to claim 1, wherein forming the insulating layer comprises:
forming a gate insulating layer on the active layer provided with the etch barrier layer;
forming an interlayer insulating layer above the gate insulating layer.

3. The method according to claim 2, further comprising:
after forming the gate insulating layer and before forming the interlayer insulating layer, forming a gate electrode on the gate insulating layer between two adjacent interlayer via holes; and
after forming the interlayer insulating layer, forming source/drain electrodes on the interlayer insulating layer, the source/drain electrodes being connected with the active layer through the via holes.

4. The method according to claim 1, wherein the etch barrier layer is a metal layer or a doped semiconductor layer.

5. The method according to claim 3, wherein the etch barrier layer is made of a material the same as that of the source/drain electrodes.

6. The method according to claim 4, wherein the etch barrier layer is one of a molybdenum metal film, an aluminum metal film, and a copper film, or one of a laminated structure of titanium/aluminum/titanium and a laminated structure of molybdenum/aluminum neodymium/molybdenum.

7. The method according to claim 1, wherein
the active layer is a polysilicon active layer.

8. The method according to claim 1, wherein forming the active layer comprises:
forming a buffer layer on a substrate;
forming an amorphous silicon layer on the buffer layer;
converting the amorphous silicon layer into a polysilicon layer;
etching the polysilicon layer to form the active layer of the thin film transistor;
doping partial regions of the active layer to form doped semiconductor regions;
alternatively, forming the active layer comprises:
forming a buffer layer on a substrate;
forming an amorphous silicon layer on the buffer layer;
converting the amorphous silicon layer into a polysilicon layer:
doping partial regions of the polysilicon layer to form doped semiconductor regions;
etching the doped polysilicon layer to form a polysilicon active layer of the thin film transistor.

9. The method according to claim 1, wherein
the etch barrier layer has a thickness of 500 Å˜3000 Å.

10. A thin film transistor, comprising:
an active layer;
an etch barrier layer used to protect the active layer upon etching interlayer via holes and disposed on the active layer at a position for forming the interlayer via holes; and
source/drain electrodes, electrically connected with the active layer through the interlayer via holes.

11. The thin film transistor according to claim 10, further comprising:
a gate insulating layer disposed on the active layer and the etch barrier layer;
a gate electrode disposed on the gate insulating layer;
an interlayer insulating layer disposed above the gate electrode;
wherein the interlayer via holes penetrate through the interlayer insulating layer and the gate insulating layer thereunder.

12. The thin film transistor according to claim 10, wherein the etch barrier layer is a metal layer or a doped semiconductor layer.

13. The thin film transistor according to claim 10, wherein the etching barrier layer is made of a material the same as that of the source/drain electrodes.

14. The thin film transistor according to claim 13, wherein the etch barrier layer is one of a molybdenum metal film, an aluminum metal film, and a copper film, or one of a laminated structure of titanium/aluminum/titanium and a laminated structure of molybdenum/aluminum neodymium/molybdenum.

15. The thin film transistor according to claim 10, wherein the active layer is a polysilicon active layer.

16. The thin film transistor according to claim 10, wherein the etch barrier layer has a thickness of 500 Å˜3000 Å.

17. An array substrate, comprising the thin film transistor according to claim 10.

18. (canceled)

19. The method according to claim 2, wherein the etch barrier layer is a metal layer or a doped semiconductor layer.

20. The method according to claim 2, wherein the active layer is a polysilicon active layer.
